(19) United States
(12) Patent Application Publication
(10) Pub. No.: US 2007/0023698 A1
(43) Pub. Date: Feb. 1, 2007

(54) ION IMPLANTING APPARATUS AND METHOD

(75) Inventor: Geum-Sik PARK, Gyeonggi-do, (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-Do, (KR)

(21) Appl. No.: 11/457,775

(22) Filed: Jul. 14, 2006

(30) Foreign Application Priority Data
Jul. 15, 2005 (KR) 2005-0064421

(51) Int. Cl. H01J 37/08

(52) U.S. Cl. 250/492.21

(57) ABSTRACT

An ion implanting apparatus and method are provided. The apparatus includes a plurality of dummy wafers and a plurality of dummy wafer cassettes. The dummy wafers are separately used for respective kinds of ions, and the plurality of dummy wafer cassettes separately store the dummy wafers separately used for the respective kinds of ions. The plurality of dummy wafer cassettes are installed in order to store the plurality of dummy wafers for the respective kinds of ions and use the dummy wafers for an ion implanting process.

This U.S. non-provisional patent application claims priority under 35 U.S.C. § 119 from Korean Patent Application 2005-64421 filed on Jul. 15, 2005, the entire contents of which are hereby incorporated by reference.

### BACKGROUND

1. Field of the Invention

The present invention relates to a semiconductor manufacturing apparatus and method, and more particularly, to an ion implanting apparatus and method for implanting ions in a wafer.

2. Description of the Related Art

Ion implanting is a process of forming a conductive region having a desired conduction characteristic by doping an object with a predetermined kind of ions. Particularly, in a semiconductor industry, the ion implanting is widely used for precisely forming a thin region having a desired impurity concentration in a wafer. The semiconductor ion implanting process may be roughly classified into two processes, that is, a single type process of processing a wafer one by one, and a batch type process of collectively processing a plurality of wafers.

Here, an ion implanting apparatus used for the batch type process may load a dummy wafer on a rotating disk when processing a plurality of wafers. When the dummy wafer is not loaded on the rotating disk, a susceptor for supporting the wafer may be contaminated, which hinders stable loading of a new wafer. The dummy wafer is stored in a dummy wafer cassette of the ion implanting apparatus.

In a related art, only a single dummy wafer cassette is installed and a dummy wafer is shared. Accordingly, a variety of dopants such as B, P, and As used during the ion implanting process may be mixed with one another and accumulated in the dummy wafer. The dummy wafer in which various dopants are mixed and accumulated may cause so called “cross contamination” which contaminates a wafer to be normally processed.

### SUMMARY

The present invention provides an ion implanting apparatus and method in which cross contamination originating from a dummy wafer does not occur.

Embodiments of the present invention provide an ion implanting apparatus including a plurality of dummy wafer cassettes for separately storing dummy wafers for respective dopants.

Embodiments of the present invention provide an ion implanting apparatus for implanting predetermined ions in a plurality of wafers including a dummy wafer, the ion implanting apparatus including: a plurality of dummy wafers separately used for respective kinds of ions; and a plurality of dummy wafer cassettes for separately storing the dummy wafers separately used for the respective kinds of ions.

The ion implanting apparatus further includes a disk for mounting the plurality of wafers thereon. The disk includes a plurality of susceptors for mounting the plurality of wafers on the susceptors.

The ion implanting apparatus further includes a motor combined with the disk, for providing a driving force to rotate the disk. The ion implanting apparatus further includes a motor combined with the disk, for providing a driving force moving the disk linearly, e.g., in a straight line.

The ion implanting apparatus further includes an ion beam generator for generating a beam containing predetermined kinds of ions to be implanted in the plurality of wafers mounted on the disk.

The disk is installed in a process chamber for providing a vacuum environment. The process chamber comprises a vacuum pump operating to provide the vacuum environment.

The process chamber is combined with a loadlock chamber for providing a wafer on the disk.

Embodiments of the present invention provide an ion implanting apparatus including: a process chamber including a rotating disk mounting a plurality of wafers including dummy wafers thereon; an ion beam generator for generating an ion beam containing predetermined kinds of ions to be implanted in the plurality of wafers mounted on the disk; and dummy wafer cassettes for storing the dummy wafers, wherein the dummy wafers are mounted on the rotating disk and used for respective kinds of the predetermined ions, and the dummy wafer cassettes store the plurality of dummy wafers for the respective kinds of the predetermined ions.

The rotating disk may be moved in a straight line. The rotating disk includes a plurality of susceptors on each of which the plurality of wafers are loaded.

The ion implanting apparatus further includes a loadlock chamber combined with the process chamber, for providing a wafer to the disk. The ion implanting apparatus further includes a vacuum pump for providing a vacuum environment to the inside of the process chamber.

According to the present invention, a plurality of dummy wafers are installed to store the dummy wafers for respective dopants so that the dummy wafers may be used during the ion implantation process, which solves a cross contamination problem caused by sharing of a single dummy wafer.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a plan view of an ion implanting apparatus according to an embodiment of the present invention;

FIG. 2 is a front view of a rotating disk in an ion implanting apparatus according to an embodiment of the present invention; and

FIG. 3 is a sectional view illustrating part of an ion implanting apparatus according to an embodiment of the present invention.

### DETAILED DESCRIPTION

Reference will now be made in detail to the preferred embodiments of the present invention, examples of which are illustrated in the accompanying drawings. However, the present invention is not limited to the embodiments illustrated hereinafter, and the embodiments herein are rather introduced to provide easy and complete understanding of the scope and spirit of the present invention. Like reference numerals in the drawings denote like elements.

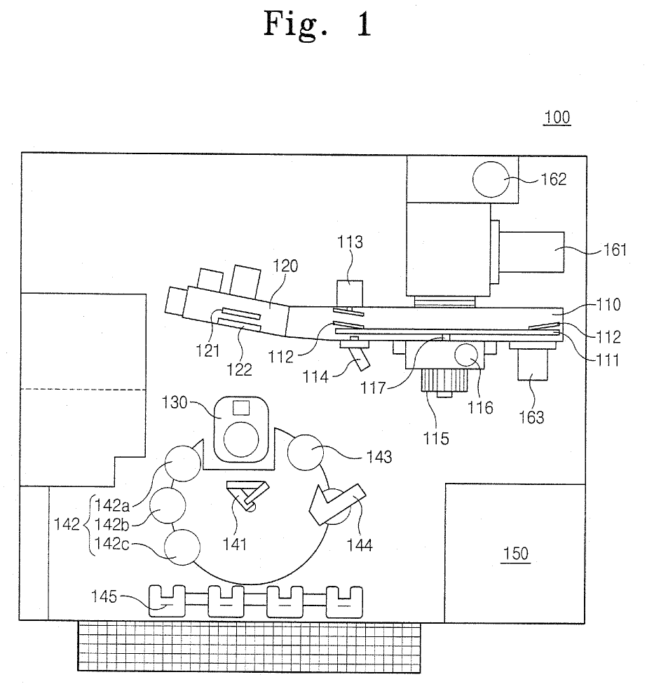

FIG. 1 is a plan view of an ion implanting apparatus according to an embodiment of the present invention. Referring to FIG. 1, an ion implanting apparatus 100 according to an embodiment of the present invention includes a process chamber 110, which is a space where an ion implantation process is actually performed. A rotating disk 111 for loading the plurality of wafers is disposed in the process chamber 110. The rotating disk 111 may mount a plurality of wafers on the rotating disk 111 using a plurality of susceptors 112. The susceptor 112 may be installed around the front outer edges of the rotating disk 111 that receive an ion beam required for the ion implantation process.

The process chamber 110 including the rotating disk 111 defines an evacuated hermetic space using vacuum pumps 161, 162, and 163 such as CRYO pumps. The vacuum pumps 161 to 163 may be installed at the front and rear sides of the process chamber 110.

The rotating disk 111 receives rotational force from a rotary drive motor 115 located in the rear side of the rotating disk 111 to rotate in high speed around a shaft 117. As the rotating disk 111 rotates, predetermined ions are implanted on the surfaces of the plurality of wafers mounted by the susceptors 112. A Y-axis scan motor 116 may be preferably installed on the rotating disk 111 to vertically move the rotating disk 111. When the rotating disk 111 can be both rotated and vertically moved, the wafer can be uniformly doped.

A wafer holder 113 is located on the front side of the process chamber 110, and a pin actuator 114 is located on the backside of the process chamber 110. Loading and unloading of a wafer to and from the susceptor 112 are achieved using wafer holder 113 and the pin actuator 114. The loading of the wafer to the process chamber 110 is achieved by operation of a wafer transfer arm 121 within a loadlock chamber 120. A wafer is transferred to the loadlock chamber 120 through a loadlock valve 122, the transferred wafer is delivered to the process chamber 110 by the wafer transfer arm 121, and mounted in the susceptors 112. The wafer is stored in a vacuum loadlock cassette 130. Transfer of the wafer herein is performed by a robot 141.

The ion implanting apparatus 100 further includes a flat aligner 144 for aligning a wafer, a buffer cassette 143, a cassette shifter 145, and an operator interface 150.

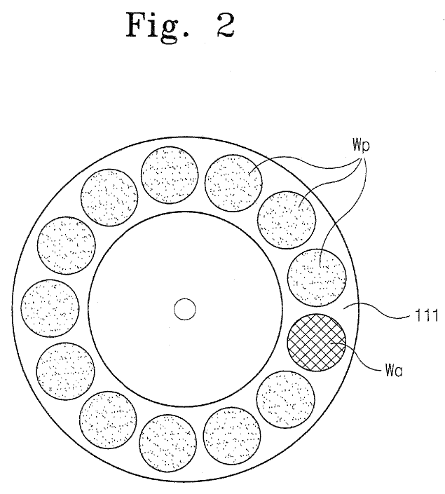

FIG. 2 is a front view of a rotating disk in an ion implanting apparatus according to an embodiment of the present invention. Referring to FIGS. 1 and 2, according to the ion implanting apparatus 100 used for the batch type process, the number of wafers loaded on the rotating disk 111 may be thirteen. An ion implantation process may be performed two times in total in order to implant ions in all of the wafers for each wafer lot to be processed. As an example, each wafer lot may include twenty-five wafers. However, since one wafer is additionally needed during a second time of ion implantation process, a dummy wafer Wd is loaded on the rotating disk 111 besides normal wafers. If the dummy wafer is not loaded on the rotating disk 111, the susceptors 112 for supporting the wafer may be contaminated. When the susceptors 112 are contaminated, the contaminated susceptors 112 may hinder stable loading of a new wafer introduced during a subsequent ion implantation process. Therefore, the ion implanting apparatus 100 further includes a dummy wafer cassette 140 for storing a dummy wafer.

During the ion implantation process, not only one kind of predetermined ions but also various kinds of ions such as B, P, and As may be implanted in the wafer if necessary. At this point, when only a single dummy wafer is used during an ion implantation process that requires a variety of ions, various dopants (ions) are mixed together and accumulated in the single dummy wafer. When the single dummy wafer, where various dopants have been accumulated, is introduced repeatedly during multiple ion implantation processes, cross contamination, which contaminates a wafer to be normally processed, occurs.

According to some embodiments, a plurality of dummy wafer cassettes 142a, 142b, and 142c may be provided to separately store the dummy wafers to be used for respective dopants. For example, one dummy wafer cassette 142a is used for storing a dummy wafer to be used when a wafer is doped with boron (B) ions, another dummy wafer cassette 142b is used for storing another dummy wafer to be used when a wafer is doped with phosphorous (P) ions, and still another dummy wafer cassette 142c is used for storing still another dummy wafer to be used when a wafer is doped with arsenic (As) ions. When the dummy wafers are separately stored for respective dopants using the plurality of dummy wafer cassettes 142 and used when a wafer is doped with a corresponding dopant, a so-called cross contamination caused by a single dummy wafer may be prevented.

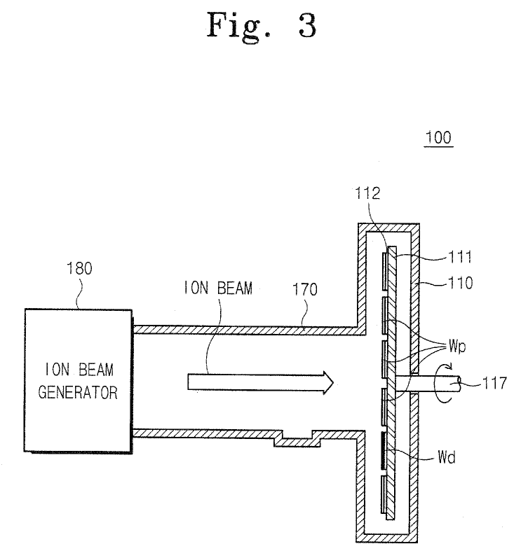

FIG. 3 is a sectional view illustrating part of an ion implanting apparatus, particularly, including an ion beam generator according to an embodiment of the present invention.

Referring to FIG. 3, the ion beam generator 180 for generating an ion beam is located in front of the process chamber 110. The ion beam generator 180 supplies an ion beam containing predetermined ions through an ion beam housing 170 onto wafers Wp and Wd mounted on the rotating disk 111. When the ion beam is provided onto the wafers Wp and Wd, predetermined portions of the wafers Wp and Wd are doped to form impurity regions such as a junction region. The wafers mounted on the rotating disk 111 may include dummy wafers Wd as well as normal wafers Wp, which are the object of the ion implantation process. Here, the dummy wafers Wd are separately provided for respective ions (dopants) used during the ion implantation process. Therefore, cross contamination, where a wafer on which ion implantation has been performed using a predetermined kind of ions is contaminated by sharing of a single dummy wafer, is prevented.

A method of preventing cross-contamination during an ion-implantation process comprises providing a disk for mounting a plurality of wafers during the ion-implantation process. Then a normal or product wafer may be mounted on the disk. Next a first dummy wafer is mounted on the disk. A first implantation process may then be carried out, thereby implanting a first kind of ions into the normal wafer and the first dummy wafer. Next, the first dummy wafer may be removed. The normal wafer may also be removed at this point and replaced with another normal wafer. A second dummy wafer may then be mounted on the disk. A second implantation process may then be carried out, thereby implanting a second kind of ions into the second dummy wafer and the normal wafer. Finally, the second dummy wafer may be removed from the disk.

According to some embodiments, the first dummy wafer may be stored in a first dummy wafer cassette situated to physically separate the first and second dummy wafers from each other. Also, the first dummy wafer may be stored in a first dummy wafer cassette and the second dummy wafer may be stored in a second dummy wafer cassette.

As described above, the plurality of dummy wafer cassettes are provided to separately store the plurality of dummy wafers for respective kinds of dopants (ions) and use the dummy wafers for the ion implantation process. Therefore, the cross contamination problem occurring when a single dummy wafer is shared is solved, which improves production yield of the wafers.

While this invention has been particularly shown and described with reference to preferred embodiments thereof, it will be understood by those skilled in the art that various changes in form and details may be made therein without departing from the spirit and scope of the invention as defined by the appended claims. The preferred embodiments should be considered in descriptive sense only and not for purposes of limitation. Therefore, the scope of the invention is defined not by the detailed description of the invention but by the appended claims, and all differences within the scope will be construed as being included in the present invention.

What is claimed is:

1. An ion implanting apparatus for implanting predetermined ions in a plurality of wafers including a dummy wafer, the ion implanting apparatus comprising:
a plurality of dummy wafers separately used for respective kinds of ions; and
a plurality of dummy wafer cassettes configured to separately store the dummy wafers.

2. The ion implanting apparatus of claim 1, further comprising a disk for mounting the plurality of wafers thereon.

3. The ion implanting apparatus of claim 2, wherein the disk comprises a plurality of susceptors for mounting the plurality of wafers on the susceptors.

4. The ion implanting apparatus of claim 2, further comprising a first motor combined with the disk, the first motor configured to rotate the disk.

5. The ion implanting apparatus of claim 4, further comprising a second motor combined with the disk, the second motor disposed to move the disk linearly.

6. The ion implanting apparatus of claim 5, wherein the second motor is disposed to move the disk in a straight line.

7. The ion implanting apparatus of claim 2, further comprising an ion beam generator configured to generate a beam containing predetermined kinds of ions to be implanted in the plurality of wafers mounted on the disk.

8. The ion implanting apparatus of claim 7, wherein the disk is installed in a process chamber, the process chamber providing a vacuum environment.

9. The ion implanting apparatus of claim 8, wherein the process chamber comprises a vacuum pump configured to provide the vacuum environment.

10. The ion implanting apparatus of claim 8, wherein the process chamber is combined with a loadlock chamber, the loadlock chamber configured to provide a wafer.

11. An ion implanting apparatus comprising:
a process chamber including a rotating disk configured to mount a plurality of wafers including dummy wafers;
an ion beam generator, the ion beam generator configured to generate an ion beam containing predetermined kinds of ions to be implanted in the plurality of wafers mounted on the disk; and
a plurality of dummy wafer cassettes, configured to store the dummy wafers,
wherein the dummy wafers are mounted on the rotating disk and configured to recieve respective kinds of ions, and the dummy wafer cassettes are configured to store the plurality of dummy wafers used for the respective kinds of ions separately.

12. The ion implanting apparatus of claim 11, wherein the rotating disk is disposed to move linearly.

13. The ion implanting apparatus of claim 12, wherein the rotating disk is disposed to move in a straight line.

14. The ion implanting apparatus of claim 11, wherein the rotating disk comprises a plurality of susceptors on each of which the plurality of wafers are loaded, respectively.

15. The ion implanting apparatus of claim 11, further comprising a loadlock chamber combined with the process chamber, for providing a wafer to the disk.

16. The ion implanting apparatus of claim 11, further comprising a vacuum pump for providing a vacuum environment to the inside of the process chamber.

17. A method of preventing cross-contamination during an ion-implantation process, the method comprising:
providing a disk configured to mount a plurality of wafers during the ion-implantation process;
mounting a normal wafer on the disk;
mounting a first dummy wafer on the disk;
implanting a first kind of ion into the normal wafer and the first dummy wafer;
removing the first dummy wafer from the disk;
mounting a second dummy wafer on the disk;
implanting a second kind of ion into the normal wafer and the second dummy wafer; and
removing the second dummy wafer from the disk.

18. The method of claim 17, further comprising storing the first dummy wafer in a first dummy wafer cassette.

19. The method of claim 18, further comprising storing the second dummy wafer in a second dummy wafer cassette.
